(19) United States
(12) Patent Application Publication
(10) Pub. No.: US 2008/0065937 A1
(43) Pub. Date: Mar. 13, 2008

(54) NAND FLASH MEMORY DEVICE WITH ECC PROTECTED RESERVED AREA FOR NON-VOLATILE STORAGE OF REDUNDANCY DATA

(75) Inventors: Rino Micheloni, Turate (IT); Roberto Ravasio, Presezzo (IT); Alessia Marelli, Dalmine (IT)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignees: STMicroelectronics S.r.I., Agrate Brianza (MI) (IT); Hynix Semiconductor Inc., Ichon-si (KR)

(21) Appl. No.: 11/854,685

(22) Filed: Sep. 13, 2007

(30) Foreign Application Priority Data
Sep. 13, 2006 (EP) 06425632.4

(51) Int. Cl. G11C 29/04

(52) U.S. Cl. 714/711; 714/E11.021

(57) ABSTRACT

Basic redundancy information is non-volatily stored in a reserved area of an addressable area of a memory array, and is copied to volatile storage therein at every power-on of the memory device. The unpredictable though statistically inevitable presence of failed array elements in such a reserved area of the memory array corrupts the basic redundancy information established during the test-on wafer (EWS) phase of the fabrication process. This increases the number of rejects, and lowers the yield of the fabrication process. This problem is addressed by writing the basic redundancy data in the reserved area of the array with an ECC technique using a certain error correction code. The error correction code may be chosen among majority codes 3, 5, 7, 15 and the like, or the Hamming code for 1, 2, 3 or more errors, as a function of the fail probability of a memory cell as determined by the EWS phase during fabrication.

### FIELD OF THE INVENTION

The present invention relates to memory devices and, more particularly, to a NAND flash memory device with an area efficient redundancy architecture.

### BACKGROUND OF THE INVENTION

In NAND type memory devices, device specific self-configuration data and redundancy data of identified failed elements of the array of memory cells and substitute elements addresses in the redundant resource area of the array are commonly stored in a non-volatile manner using dedicated fuse arrays. Fuse arrays are permanently set during the testing on wafer (EWS) phase of the devices in the fabrication process.

FIG. 1 is a simplified high level block diagram of a common NAND flash memory device in which the fuse arrays containing the basic data of redundancy and self-configuration implementation at every power-on of the device are highlighted by outlining the relative blocks with a thicker line. These blocks include the CONFIGURATION FUSES block for setting important electrical operating parameters, such as voltage levels and voltage references at every power-on of the device according to common practices. The BAD BLOCK FUSES array contains the locating data blocks of addressable memory cells of the user addressable area (MATRIX) of the memory cell array that contains a failed element during the EWS testing phase. The COLUMN REDUNDANCY FUSES array block redirects the access from a failed memory location to a substitute column of cells of a redundancy area of the memory cell array. Commonly, the addressable area (MATRIX) of the memory cell array and the redundancy resource area are provided with distinct page buffers associated to respective column decoder circuits. The scheme of FIG. 1 can be readily understood by those skilled in the art, and a description of the other illustrated architectural components shown is deemed unnecessary.

The number of redundancy resources to be utilized in fabricated devices obviously increases with increasing storage capacity of the memory devices. Unfortunately, the size of the fuses does not decrease as quickly as the size and compactness degree of cell arrays. This fact negatively reflects on the relative area ratio.

FIG. 2 shows a common representation of the arrangement of blocks of memory cells of the addressable area of the array and of failed bit lines. The representation emphasizes the integrated structures that require dedicated fuses for implementing the substitution of failed elements with equivalent redundant resources.

Possible alternatives to the implementation of an excessively large number of fuses to be set during EWS phase could be non-volatily storing the basic redundancy data in either dedicated non-volatile supports, such as UPROM structures, or in a one time programmable (OTP) array of cells belonging to a dedicated sector of the cell array.

The UPROM option implies the use of a dedicated memory array purposely integrated in the device having read circuitry that is practically distinct from the read circuitry of the NAND flash memory array. The dedicated UPROM memory array is specially designed to have a sufficiently enhanced reliability in order to generate a very high flawless probability. However, such an approach, beside an intrinsically large area requirement, is hardly applicable in the context of current NAND type flash memory device fabrication processes.

The other option contemplates the use of a portion or block or dedicated area of the flash memory cell array as a “one time programmable” memory block. Though apparently promising for non-volatily storing redundancy as well as self-configuration data, it has not found application because, in the case of NAND flash memory devices, its implementation is hindered by problems descending from the two following conditions:

a) in NAND type flash memory devices, differently from other types of flash memories, a gerarchic organization of the cell array is not implemented because it would be too burdensome in terms of silicon area requirement and, as a consequence, the cell array bitlines are common to all blocks of cells; and

b) all blocks of a certain number of word lines of array cells are commonly formed in N-type and in P-type wells formed in a P-type silicon substrate, and therefore the blocks of cells may hardly be electrically isolated from one another.

Differently from common user OTP(s) that are eventually accessed only after the substitution of failed elements with redundant resources has already been implemented following the conclusion of the power-on phase, the first condition (a) implies that any failed bitline to be eventually substituted by the redundancy architecture would still be read at power-on of the memory device. This basically corrupts any redundancy data that could be stored in a reserved area of the memory array.

The second condition (b) implies any such one time programmable reserved area would of course be subject to all the electrical stresses from all erasing operations carried out in any of the blocks of cells of the area of the array addressable by the external user of the device for the entire operating life of the device itself. Therefore, the correct reading of redundancy data from a reserved area at power-on may, in time, become even more critical.

### SUMMARY OF THE INVENTION

In view of the foregoing background, an object of the invention is to reduce silicon area requirement of a non-volatile memory device while achieving enhanced fabrication yields without significantly compromising the operating life characteristics of the device.

The basic redundancy information may be non-volatily stored in a reserved area (i.e., an area of the array that is not addressable by the user of the device) of the addressable area of the array, and may be copied on volatile storage supports at every power-on of the memory device.

The unpredictable though statistically inevitable presence of failed array elements also in such a reserved area of the memory array would likely corrupt the basic redundancy information as established during the test-on wafer (EWS) phase of the fabrication process. This may increase the number of rejects, and lower the yield of the fabrication process. This may be effectively overcome by writing the basic redundancy data in the reserved area of the array with an ECC technique. A certain error correction code may be used, and may be chosen among majority codes 3, 5, 7, 15 and the like or a Hamming code for 1, 2, 3 or more errors. This may be a function of the fail probability of a memory cell as determined by the testing on wafer of the devices during fabrication (i.e., fail probability of the specific fabrication process used).

Through an appropriate screening of the EWS test results, the corrective power of the selected ECC technique may be appropriate to handle the fail density in the reserved area. This, eventually coupled in the case of a multilevel flash memory, with the utilization of the two extreme distributions of the multilevel memory for writing the ECC protected data in the reserved area and with a single level mode reading of the data, at power-on with relatively relaxed read parameters (e.g., time intervals, voltages), may advantageously prevent or reduce negative influences on the process yield corresponding to the storing of the basic redundancy data in the non-volatile memory device array itself.

The permanently stored basic redundancy data may be read and decoded by an appropriate logic circuit at every power-on of the memory device, and relevant redundancy information may be copied in one or more, and preferably in two distinct volatile memory supports. The memory supports may become part of the redirecting circuit for user access to failed memory array locations to substitute memory array elements in the redundancy area of the cell array during normal operation of the device, following the conclusion of the power-on phase.

Besides basic redundancy data, even certain self-configuring data and program codes to be executed by the microcontroller for carrying out the memory operations as commanded by the external user may be advantageously stored in the reserved area of the memory array. This data may be written and read with the same ECC technique with relaxed reading conditions similar to the basic redundancy data.

### BRIEF DESCRIPTION OF THE DRAWINGS

FIGS. 1 and 2 are respectively a high level functional block diagram of a non-volatile page mode memory device, and a representation of the blocks and words arrangements in the addressable area and in the redundancy area of a NAND memory cell array according to the prior art.

FIG. 3 is a representation of an equivalent NAND memory cell array with graphical indications of failed array elements and of a reserved area according to the invention.

FIG. 4 is a high level functional block diagram of a non-volatile page mode memory device with the modified architecture according to the invention.

FIG. 5 shows a fail graph of different error correction codes as a function of the fail probability of a memory cell according to the invention.

### DETAILED DESCRIPTION OF THE PREFERRED EMBODIMENTS

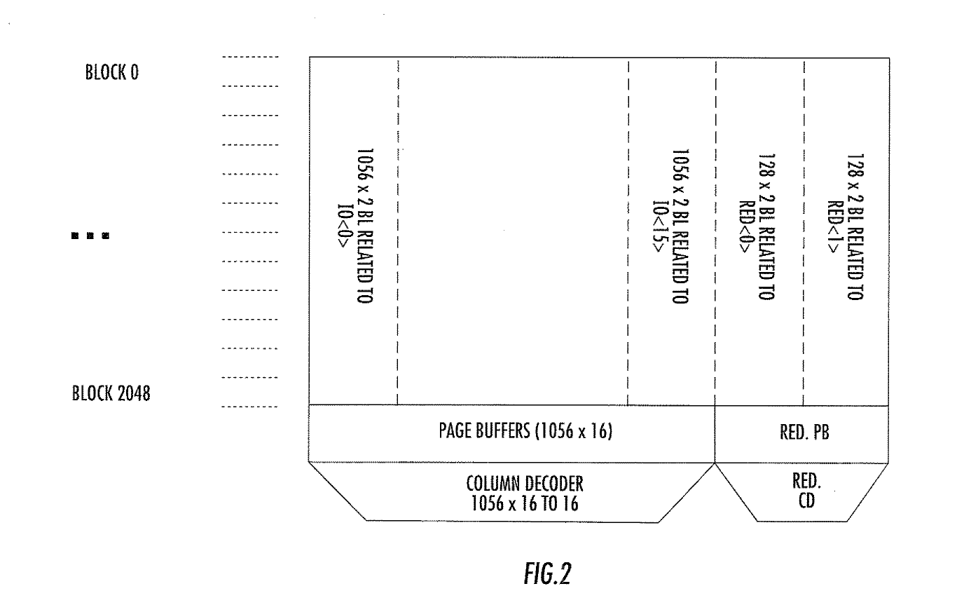

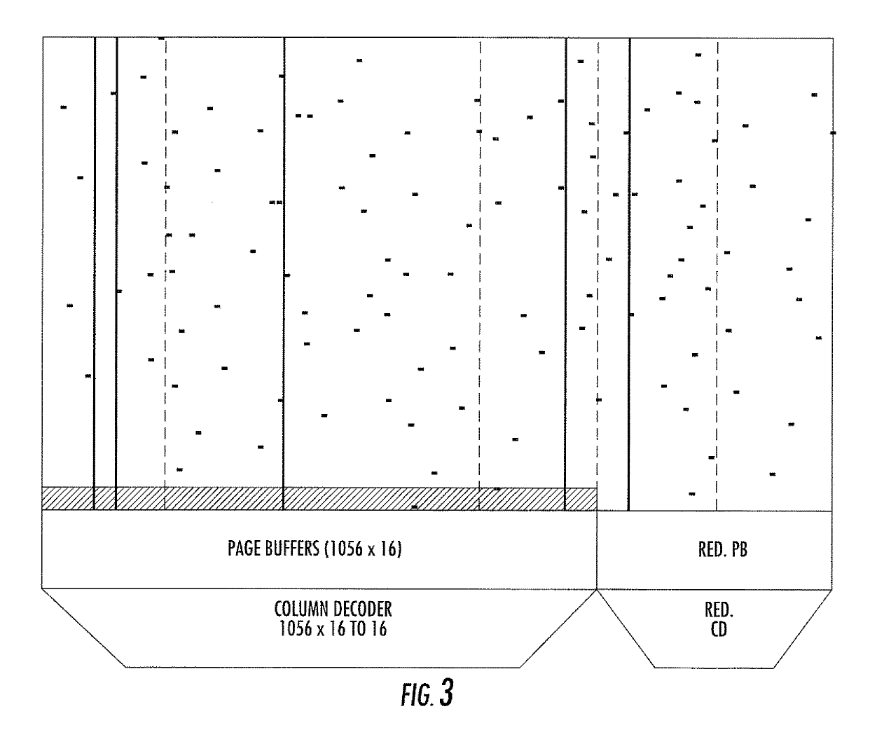

As graphically represented in FIG. 3, a reserved area RA (identified by the darkened field) that will not be addressable by the user of the EWS-tested, trimmed, repaired and finished memory device is part of the addressable area of the memory cell array. The reserved area RA may retain the same organization graphically defined in FIG. 2.

In FIG. 3, the dark dots indicate failed cells that cannot be utilized (as identified during the test-on wafer of the device), and the solid vertical lines represent failed bit lines of the array (as also identified during the test-on wafer phase). The basic redundancy data on the failed array elements identified during the EWS testing are written, during the EWS phase itself, in the reserved area RA of the addressable area of the memory cell array. This is identified by the darkened array area in FIG. 3.

The writing of the basic redundancy data in the reserved area is made with an ECC data writing technique according to a certain error correction code. Moreover, the writing of the basic redundancy data in the reserved area of the addressable memory array is carried out to ensure enhanced read margins. For example, in case of a multilevel memory device, this may be provided by using the extreme threshold voltage distributions for reading the written information in a single level read mode. This is preferably with all electrical parameters pertinent to the reading of the recorded data (read voltage levels and time intervals) relatively relaxed in order to ensure a large margin of discrimination of the recorded information.

The redundancy system of the memory device permits the reading of the basic redundancy data from the reserved area at power-on without the assistance of any information contained in the reserved area itself. Of course, at power-on, in consideration of the fact that the column redundancy information is not yet present in the volatile storage area of the circuit that implements the substitution of failed bitlines, such a re-directing function remains disabled during the early part of the power-on phase.

The following is a selection of ECC codes that may be appropriate for a modern NAND memory device fabrication process:

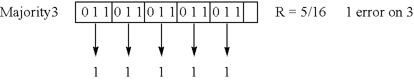

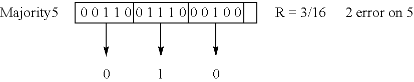

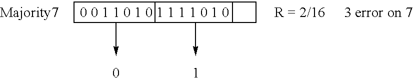

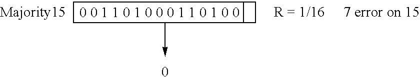

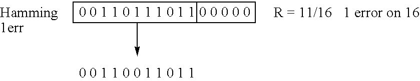

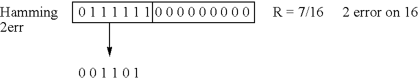

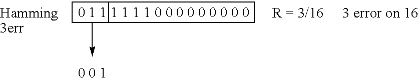

The choice of the ECC code generally will depend on the number of parity bits required, circuit complexity, correction power of the ECC technique and on the fail probability of a fabricated memory cell. For example, if the requirement is to effectively ECC protect 6144 bits of basic information to be written on the reserved area RA of the memory array, and depending on the choice of the different codes indicated above, then the reserved area will need to have a capacity as specified below.

Majority 3: Each bit is written three times, thus allowing correction of one error every three bits. There will be five effective bits of information for each word. This coding scheme requires a total number of 18432 bits, and implies a very small computational complexity.

Majority 5: Each bit is written five times, thus permitting correction of two errors every 5 bits. Three effective bits of information are present in each word. This coding scheme requires a total of 30720 bits with a very small computational complexity.

Majority 7: Each bit is written seven times, thus permitting correction of three errors every seven bits. There are two effective information bits in each word. The coding scheme requires a total of 43008 bits with a very small computational complexity.

Majority 15: Each bit is written fifteen times, thus permitting correction seven errors every five bits. In each word there will be only one effective information bit. The coding scheme will require a total of 92160 bits with a very small computational complexity.

Hamming 1err: This scheme is based on a Hamming code capable of correcting one error every fifteen bits. Each word contains eleven bits of information. The scheme requires a total of 8385 bits, and implies a moderate computational complexity.

Hamming 2err: This scheme is based on a matrix Hamming code (extended Hamming code) capable of correcting two errors every fifteen bits. Each word contains seven bits of information. The scheme requires a total 13170 bits, and a substantial computational complexity for implementing a decoding matrix that is capable of considering all conditions that may occur in presence of one or two errors.

Hamming 3err: This scheme is based on an extended matrix Hamming code capable of correcting three errors every 15 bits. Each word contains 3 bits of information. This scheme requires a total of 30720 bits with a rather complex computational circuitry burden.

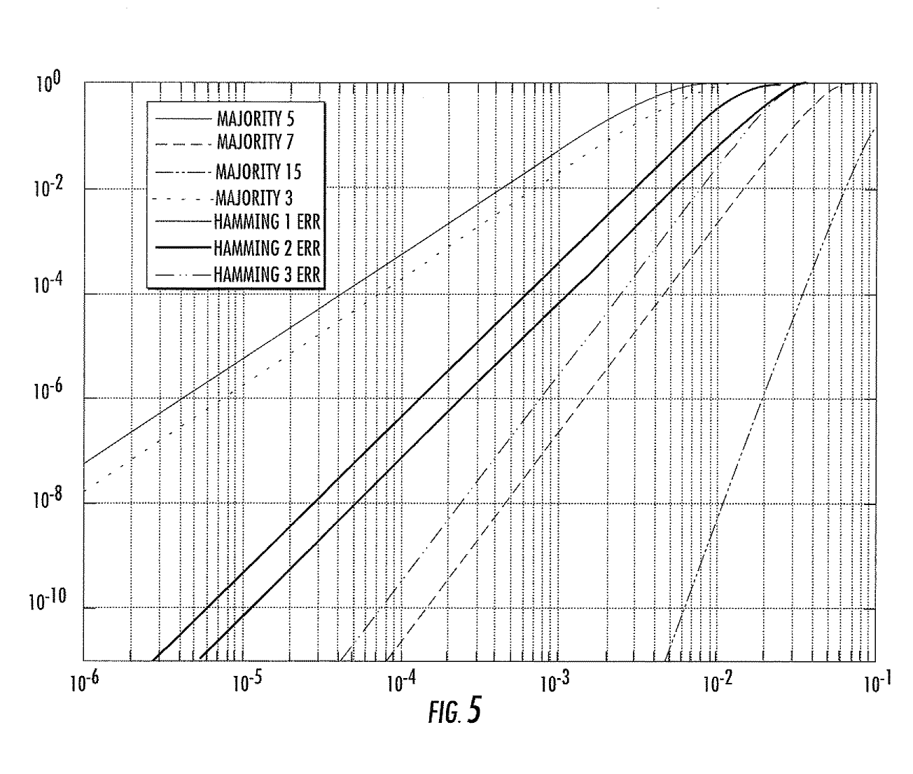

For the example considered, FIG. 5 is a graphical representation of the fail characteristics of the above-specified codes as a function of the fail probability of a fabricated cell. By assuming that the ratio of fail probabilities and of the bits lines of the cells are equal to 10⁻³, it may be observed that the ECC codes with a correction power of only one error would be unsatisfactory because they would lead to an excessively high fail probability. In contrast, the ECC correction code with a correction power of seven errors is excessive, taking into consideration the number of bits it requires.

For the considered example, the most appropriate ECC codes appear to be those with a correction power of two or three errors. The final choice will depend on the preferred compromise between the total number of bits required (that is definitely larger for the majority codes) and the associated computational circuit complexity.

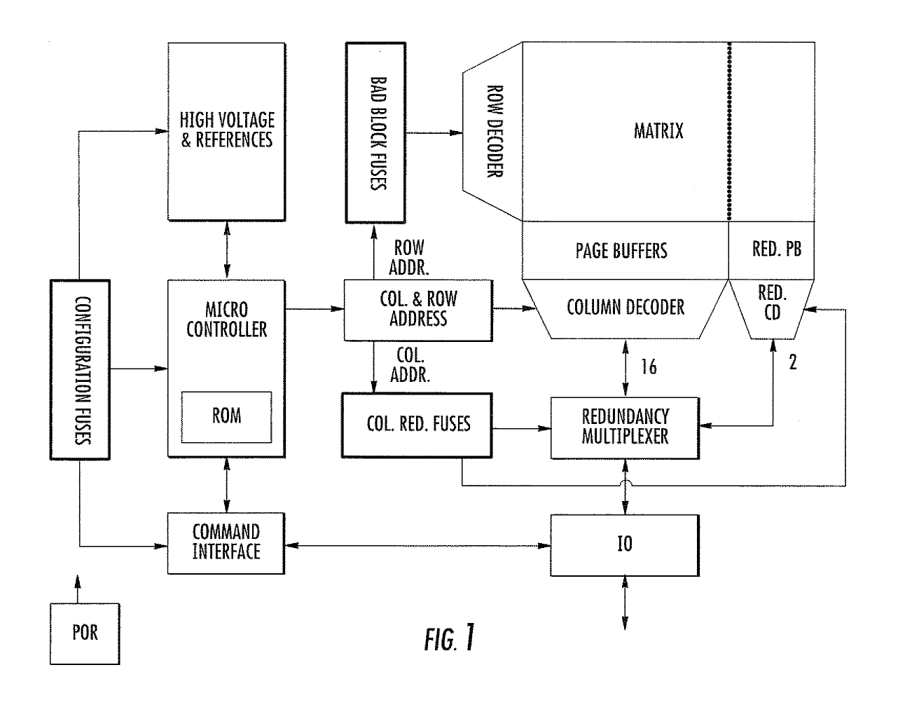

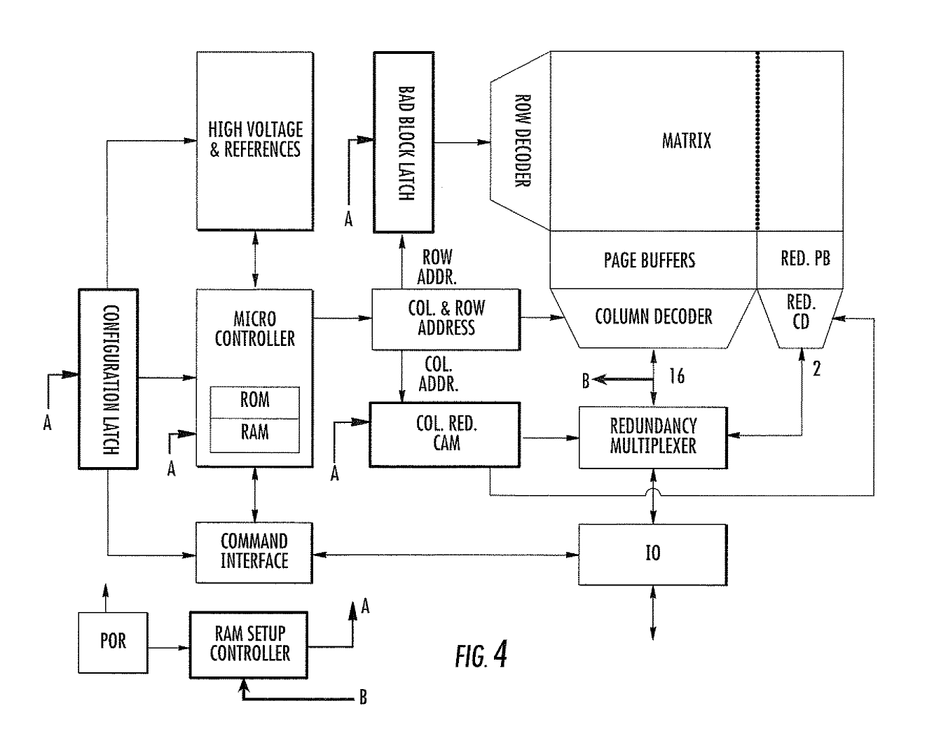

A sample block diagram of a non-volatile page mode NAND memory device is shown in FIG. 4. The characterizing features are emphasized by the blocks drawn with thicker solid lines for a more immediate comparison with the functional block diagram of the prior art device of FIG. 1.

Immediately after the power-on reset phase, the basic redundancy information non-volatily stored in the reserved area RA of the array (matrix) is read through the read circuitry of the memory device. A controller circuit RAM SETUP CONTROLLER copies the bad block addresses in a volatile buffer that is directly interfaced with the microcontroller of the memory device. Moreover, the RAM SET UP CONTROLLER block sets a CAM (content addressed memory) array COL.RED.CAM.

Optionally, as shown in the sample device architecture of FIG. 4, besides the basic redundancy data, the reserved area RA of the memory array may store specific configuration data of the device. This may include trim voltage and timing interval values as defined for the fabrication memory device during the EWS phase, for example. This configuring data is similarly read immediately after the power-on reset phase, and is copied by the block RAM SETUP CONTROLLER in the block of CONFIGURATION LATCH. This is for trimming the high voltage and voltage reference generator block. Other configuration data to be thereafter accessed by the microcontroller in executing the power-on configuration programs may also be copied on the volatile support immediately after the power-on reset phase.

Upon terminating the power-on phase, the device will be ready to operate. The volatile redundancy data storing blocks, namely the BAD BLOCK LATCH and the COL.RED.CAM block, become part of the circuit that carries out the redundancy substitution of failed array elements at every power-on of the device.

1-8. (canceled)

9. A non-volatile memory device comprising:
an array of memory cells organized in a NAND configuration, and divided into an addressable area and a redundancy area;
the addressable area including a reserved area that is not addressable by a user of the memory device, the reserved area for storing failed memory location data using an error protected data writing technique according to an error correction code so that a reading of the data is uncorrupted at power-on when failed array elements are in the reserved area;
a microcontroller operating in response to external commands, and comprising a non-volatile memory for executing program codes resident therein for self-configuring said array by substituting failed blocks of memory array cells containing at least one failed array element in the addressable area with an equivalent at least one array element from the redundancy area;
a row decoder coupled to rows of said array;
a column decoder coupled to columns of said array;
a plurality of page buffers associated with said column decoder and the addressable and redundancy areas of said array; and
a re-direction circuit for storing failed memory location data for the addressable area of said array for re-directing substitute memory array elements in the redundancy area, said re-direction circuit comprising
a logic circuit for decoding the read data according to the error correcting code used in writing the data in the reserved area,
at least one first non-volatile data storage for storing data on the failed blocks of memory array cells in the addressable area,
at least one second non-volatile data storage for data on the failed bitlines in the addressable area, and
said at least one first and second non-volatile data storages for copying decoded re-directing information read from the reserved area at power-on.

10. The non-volatile memory device of claim 9, wherein said at least one first non-volatile data storage is configured as a RAM buffer interfacing said microcontroller.

11. The non-volatile memory device of claim 9, wherein said at least one second non-volatile data storage is configured as a content addressed memory array operating in response to column and row addresses generated by said microcontroller for re-directing user access to substituted bitlines in the redundancy area.

12. The non-volatile memory device of claim 9, wherein the reserved area of the addressable area is written with a same redundant data writing technique according to the error correction code, and wherein self-configuration data of the memory device used in execution of a self-configuring program code executed by said microcontroller at power-on is written with the same redundant data writing technique according to the error correction code; and further comprising an additional latch array in which the self-configuration data read from the reserved area is copied at power-on.

13. The non-volatile memory device of claim 9, wherein data is written based on 16-bit words, and wherein the error correction code comprises at least one of majority codes 3, 5, 7, 15 and Hamming codes for 1, 2 and 3 errors, depending on a fail probability of a memory cell.

14. The non-volatile memory device of claim 9, wherein the data read from the reserved area of said array is based on a single level mode.

15. The non-volatile memory device of claim 9, further comprising a non-volatile RAM buffer; and wherein the program codes to be executed by said microcontroller are stored in the reserved area of said array, except for boot-up program codes, and with the program codes also being copied in said non-volatile RAM buffer at power-on.

16. A memory device comprising:
an array of memory cells divided into an addressable area and a redundancy area;
the addressable area including a reserved area that is not addressable by a user of the memory device, the reserved area for storing failed memory location data using an error protected data writing technique according to an error correction code so that a reading of the data is uncorrupted at power-on when failed array elements are in the reserved area;
a microcontroller operating in response to external commands, and for executing program codes for self-configuring said array by substituting failed blocks of memory array cells containing at least one failed array element in the addressable area with an equivalent at least one array element from the redundancy area; and
a re-direction circuit for storing failed memory location data for the addressable area of said array for re-directing substitute memory array elements in the redundancy area, said re-direction circuit comprising
a logic circuit for decoding the read data according to the error correcting code used in writing the data in the reserved area,
at least one first non-volatile data storage for storing data on the failed blocks of memory array cells in the addressable area,
at least one second non-volatile data storage for data on the failed bitlines in the addressable area, and
said at least one first and second non-volatile data storages for copying decoded re-directing information read from the reserved area at power-on.

17. The memory device of claim 15, further comprising:
a row decoder coupled to rows of said array;
a column decoder coupled to columns of said array; and
a plurality of buffers associated with said column decoder and the addressable and redundancy areas of said array.

18. The memory device of claim 15, wherein said at least one first non-volatile data storage is configured as a buffer interfacing said microcontroller.

19. The memory device of claim 15, wherein said at least one second non-volatile data storage is configured as a content addressed memory array operating in response to column and row addresses generated by said microcontroller for re-directing user access to substituted bitlines in the redundancy area.

20. The memory device of claim 15, wherein the reserved area of the addressable area is written with a same redundant data writing technique according to the error correction code, and wherein self-configuration data of the memory device used in execution of a self-configuring program code executed by said microcontroller at power-on is written with the same redundant data writing technique according to the error correction code; and further comprising an additional latch array in which the self-configuration data read from the reserved area is copied at power-on.

21. The memory device of claim 15, wherein data is written based on 16-bit words, and wherein the error correction code comprises at least one of majority codes 3, 5, 7, 15 and Hamming codes for 1, 2 and 3 errors, depending on a fail probability of a memory cell.

22. The memory device of claim 15, wherein the data read from the reserved area of said array is based on a single level mode.

23. The memory device of claim 15, further comprising a non-volatile buffer; and wherein the program codes to be executed by said microcontroller are stored in the reserved area of said array, except for boot-up program codes, and with the program codes also being copied in said non-volatile buffer at power-on.

24. A method of substituting failed array elements of a non-volatile memory device comprising an array of memory cells divided into an addressable area and a redundancy area; a microcontroller operating in response to external commands for executing program codes for self-configuring the array by substituting failed blocks of memory array cells containing at least one failed array element in the addressable area with an equivalent at least one array element from the redundancy area; and a re-direction circuit for storing failed memory location data for the addressable area of the array for re-directing substitute memory array elements in the redundancy area, the method comprising:
determining during a test-on-wafer phase a fail probability of fabricated cells and of array bit lines;
selecting an error correction code for writing data for the determined fail probabilities;
reserving an area of the addressable area of the array that is not addressable by a user of the memory device, the reserved area for storing failed memory location data as determined during the test-on-wafer phase using an error protected data writing technique according to an error correction code so that a reading of the data is uncorrupted at power-on;
reading and decoding the failed memory location data from the reserved area at power-on, following a power-on reset phase;
copying failed block data of the addressable area of the array in a first non-volatile data storage, and copying failed bit line data for the addressable area in a second non-volatile data storage; and
re-directing the substitute memory array elements to the failed memory locations based on the microcontroller accessing the first non-volatile data storage and the second non-volatile data storage for.

25. The method of claim 23, wherein the at least one first non-volatile data storage is configured as a RAM buffer interfacing the microcontroller.

26. The method of claim 23, wherein the at least one second non-volatile data storage is configured as a content addressed memory array operating in response to column and row addresses generated by the microcontroller for re-directing user access to substituted bitlines in the redundancy area.

27. The method of claim 23, wherein the reserved area of the addressable area is written with a same redundant data writing technique according to the error correction code, and wherein self-configuration data of the memory device used in execution of a self-configuring program code executed by the microcontroller at power-on is written with the same redundant data writing technique according to the error correction code; and further comprising an additional latch array in which the self-configuration data read from the reserved area is copied at power-on.

28. The method of claim 23, wherein data is written based on 16-bit words, and wherein the error correction code comprises at least one of majority codes 3, 5, 7, 15 and Hamming codes for 1, 2 and 3 errors, depending on a fail probability of a memory cell.

29. The method of claim 23, wherein the data read from the reserved area of the array is based on a single level mode.

30. The method of claim 23, wherein the program codes to be executed by the microcontroller are stored in the reserved area of the array, except for boot-up program codes, and with the program codes also being copied in a non-volatile RAM buffer at power-on.
